(19) United States
(12) Patent Application Publication
(10) Pub. No.: US 2025/0048838 A1
(43) Pub. Date: Feb. 6, 2025

(54) LIGHT EMITTING DEVICE, DISPLAY DEVICE, PHOTOELECTRIC CONVERSION DEVICE, ELECTRONIC APPARATUS, AND MANUFACTURING METHOD OF LIGHT EMITTING DEVICE

(71) Applicant: CANON KABUSHIKI KAISHA, Tokyo (JP)

(72) Inventor: NOBUAKI KAKINUMA, Tokyo (JP)

(21) Appl. No.: 18/922,877

(22) Filed: Oct. 22, 2024

Related U.S. Application Data
(63) Continuation of application No. PCT/JP2023/010538, filed on Mar. 17, 2023.

(30) Foreign Application Priority Data
May 31, 2022 (JP) 2022-088876
Dec. 20, 2022 (JP) 2022-203534

(51) Int. Cl. H10K 59/121; H10K 59/12; H10K 59/122; H10K 59/131; H10K 59/60

(52) U.S. Cl. CPC H10K 59/1213; H10K 59/1201; H10K 59/122; H10K 59/131; H10K 59/60

(57) ABSTRACT

A light emitting device is provided. The device includes a first substrate that includes a first main surface and a second main surface on which a light emitting element is arranged, and a second substrate bonded to the first main surface. A transistor configured to control the light emitting element is arranged in the first substrate, the transistor includes a gate electrode extending in a direction intersecting the first main surface, a first diffusion region arranged in the first main surface and functioning as one of a source region and a drain region, and a second diffusion region arranged in the second main surface and functioning as another of the source region and the drain region, and the first diffusion region and the second diffusion region are arranged in the intersecting direction.

### CROSS-REFERENCE TO RELATED APPLICATIONS

This application is a Continuation of International Patent Application No. PCT/JP2023/010538, filed Mar. 17, 2023, which claims the benefit of Japanese Patent Application No. 2022-088876 filed May 31, 2022, and Japanese Patent Application No. 2022-203534 filed Dec. 20, 2022, all of which are hereby incorporated by reference herein in their entirety.

### BACKGROUND OF THE INVENTION

### Field of the Invention

The present invention relates to a light emitting device, a display device, a photoelectric conversion device, an electronic apparatus, and a manufacturing method of the light emitting device.

### Background Art

PTL 1 describes a semiconductor device in which the first substrate including a transistor that drives a light emitting element and the second substrate including a transistor that drives a light receiving element are stacked. In the semiconductor device described in PTL 1, the light emitting element, the light receiving element, and a through electrode that extends through the first substrate and transmits a driving signal for the light emitting element from the second substrate are arranged in the first substrate.

### CITATION LIST

### Patent Literature

PTL 1: Japanese Patent Laid-Open No. 2018-174246

When a light emitting element is arranged on one main surface of one substrate and a transistor is arranged on the other main surface as described in PTL 1, the degree of freedom of the layout of the light emitting element and the transistor increases. However, the transistor cannot be arranged in the portion where a through electrode is arranged, and this can hinder a high pixel density.

The present invention has as its object to provide a technique advantageous in increasing the density.

### SUMMARY OF THE INVENTION

According to some embodiments, a light emitting device comprising a first substrate that includes a first main surface and a second main surface on which a light emitting element is arranged, and a second substrate bonded to the first main surface, wherein a transistor configured to control the light emitting element is arranged in the first substrate, the transistor includes a gate electrode extending in a direction intersecting the first main surface, a first diffusion region arranged in the first main surface and functioning as one of a source region and a drain region, and a second diffusion region arranged in the second main surface and functioning as another of the source region and the drain region, and the first diffusion region and the second diffusion region are arranged in the intersecting direction, is provided.

According to some other embodiments, a manufacturing method of a light emitting device including a first substrate that includes a first main surface and a second main surface on which a light emitting element is arranged, and a second substrate bonded to the first main surface, wherein a transistor configured to control the light emitting element is arranged in the first substrate, the transistor includes a gate electrode extending in a direction intersecting the first main surface, a first diffusion region arranged in the first main surface and functioning as one of a source region and a drain region, and a second diffusion region arranged in the second main surface and functioning as another of the source region and the drain region, the first diffusion region and the second diffusion region are arranged in the intersecting direction, the method comprises: a step of preparing an SOI substrate as the first substrate; and a polishing step of polishing the SOI substrate, and the second main surface is a surface of the SOI substrate polished in the polishing step, is provided.

According to still other embodiments, a manufacturing method of a light emitting device including a first substrate that includes a first main surface and a second main surface on which a light emitting element is arranged, and a second substrate bonded to the first main surface, wherein a transistor configured to control the light emitting element is arranged in the first substrate, the transistor includes a gate electrode extending in a direction intersecting the first main surface, a first diffusion region arranged in the first main surface and functioning as one of a source region and a drain region, and a second diffusion region arranged in the second main surface and functioning as another of the source region and the drain region, the first diffusion region and the second diffusion region are arranged in the intersecting direction, the method comprises a step of preparing, as the first substrate, an epitaxial substrate including a first layer and a second layer epitaxially grown on the first layer and having a lower impurity concentration than the first layer, a part of the first layer functions as the first diffusion region, and a part of the second layer functions as a well region between the first diffusion region and the second diffusion region, is provided.

Further features of the present invention will become apparent from the following description of exemplary embodiments with reference to the attached drawings.

### BRIEF DESCRIPTION OF THE DRAWINGS

The accompanying drawings, which are incorporated in and constitute a part of the specification, illustrate embodiments of the invention and, together with the description, serve to explain principles of the invention.

FIG. 1A is a sectional view showing an arrangement example of a light emitting device according to an embodiment.

FIG. 1B is a plan view showing the arrangement example of the light emitting device according to the embodiment.

FIG. 2A is a sectional view showing a modification of the light emitting device shown in FIGS. 1A and 1B.

FIG. 2B is a plan view showing the modification of the light emitting device shown in FIGS. 1A and 1B.

FIG. 3 is a sectional view showing a modification of the light emitting device shown in FIGS. 2A and 2B.

FIG. 4 is a sectional view showing a modification of the light emitting device shown in FIG. 3.

FIG. 5 is a sectional view showing a modification of the light emitting device shown in FIGS. 1A and 1B.

FIG. 6 is a sectional view showing a modification of the light emitting device shown in FIGS. 2A and 2B.

FIG. 7A is a plan view of the light emitting device shown in FIG. 6.

FIG. 7B is a plan view of the light emitting device shown in FIG. 6.

FIG. 7C is a circuit diagram of the light emitting device shown in FIG. 6.

FIG. 8 is a sectional view showing a modification of the light emitting device shown in FIGS. 2A and 2B.

FIG. 9A is a plan view of the light emitting device shown in FIG. 8.

FIG. 9B is a plan view of the light emitting device shown in FIG. 8.

FIG. 9C is a circuit diagram of the light emitting device shown in FIG. 8.

FIG. 10 is a sectional view showing a modification of the light emitting device shown in FIGS. 1A and 1B.

FIG. 11 is a view showing an arrangement example of the pixel circuit of the light emitting device shown in FIGS. 1A and 1B.

FIG. 12 is a sectional view of a light emitting device including the pixel circuit shown in FIG. 11.

FIG. 13 is a view showing an example of a display device using the light emitting device according to the embodiment.

FIG. 14 is a view showing an example of a photoelectric conversion device using the light emitting device according to the embodiment.

FIG. 15 is a view showing an example of an electronic apparatus using the light emitting device according to the embodiment.

FIG. 16A is a view showing an example of a display device using the light emitting device according to the embodiment.

FIG. 16B is a view showing an example of a display device using the light emitting device according to the embodiment.

FIG. 17 is a view showing an example of an illumination device using the light emitting device according to the embodiment.

FIG. 18 is a view showing an example of a moving body using the light emitting device according to the embodiment.

FIG. 19A is a view showing an example of a wearable device using the light emitting device according to the embodiment.

FIG. 19B is a view showing an example of a wearable device using the light emitting device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

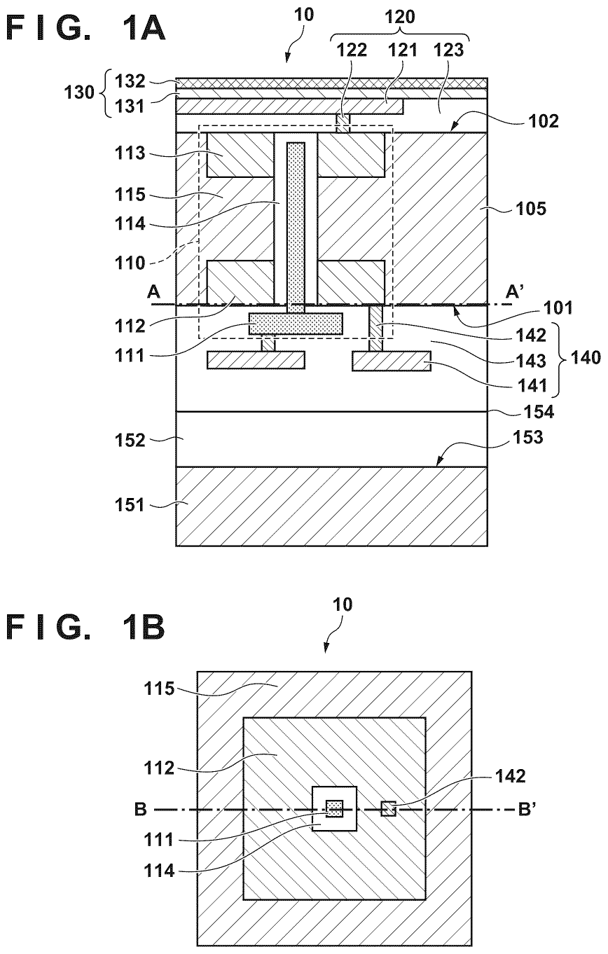

With reference to FIGS. 1A and 1B to 12, a light emitting device according to an embodiment of the present disclosure will be described. FIG. 1A is a sectional view showing an arrangement example of a light emitting device 10 in this embodiment. The light emitting device 10 includes a substrate 105 including a main surface 101 and a main surface 102 on which a light emitting element 130 is arranged, and a substrate 151 bonded to the main surface 101 of the substrate 105 via insulating layers 143 and 152. The substrate 105 and the substrate 151 can be semiconductor substrates using, for example, silicon or the like. The substrate 151 may be an insulating substrate using glass, a resin, or the like. The substrate 151 can also be called a support substrate.

The main surface 101 of the substrate 105 is arranged to face the substrate 151 and bonded to the substrate 151. A wiring structure 120 and the light emitting element 130 are formed on the main surface 102 on the opposite side of the main surface 101 of the substrate.

A transistor 110 that controls the light emitting element 130 is arranged in the substrate 105. The transistor 110 includes a gate electrode 111 extending in a direction intersecting the main surface 101 of the substrate 105, a diffusion region 112 arranged in the main surface 101 of the substrate 105 and functioning as one of a source region and a drain region, and a diffusion region 113 arranged in the main surface 102 of the substrate 105 and functioning as the other of the source region and the drain region. As shown in FIG. 1A, the diffusion region 112 and the diffusion region 113 are arranged side by side in the direction intersecting the main surface 101 of the substrate 105. The transistor 110 also includes a gate insulating film 114 and a well region 115. Here, the expression “the diffusion region 112 arranged in the main surface 101 of the substrate 105” is not limited to a case where the diffusion region 112 is exposed as the main surface 101. For example, an insulating layer made of silicon oxide or the like may be arranged on the diffusion region 112. This also applies to the diffusion region 113 and the like. The diffusion regions 112 and 113 may be semiconductor regions having a conductivity type different from that of the well region 115. The diffusion regions 112 and 113 may be regions with impurity concentrations 10 times or higher than that of the well region 115. When a predetermined voltage is applied to the gate electrode 111 of the transistor 110, a channel region is formed near the interface between the well region 115 and the gate insulating film 114, and a current flows between the diffusion region 112 and the diffusion region 113. That is, the transistor 110 is a switch element capable of causing a current to flow between an electrode in contact with the diffusion region 112 arranged in the main surface 101 of the substrate 105 and an electrode in contact with the diffusion region 113 arranged in the main surface 102.

The wiring structure 120 includes a wiring pattern 121, a plug 122, and an insulating layer 123. FIG. 1A shows the wiring pattern 121 in one layer, but the wiring pattern may be arranged across a plurality of layers. The wiring pattern 121 and the plug 122 can be formed using, for example, a metal such as copper, tungsten, titanium, or aluminum, or an alloy thereof. A barrier layer using tantalum, tantalum nitride, or the like may be arranged between the insulating layer 123 and each of the wiring pattern 121 and the plug 122. The insulating layer 123 can be formed using, for example, silicon oxide, silicon nitride, silicon oxynitride, or silicon carbide.

The light emitting element 130 includes a lower electrode, a light emitting layer 131, and an upper electrode 132. The arrangement shown in FIG. 1A shows an example where the wiring pattern 121 is also used as the lower electrode of the light emitting element 130, but the lower electrode is not limited to this. The lower electrode of the light emitting element 130 may be arranged separately from the wiring pattern 121. In the arrangement shown in FIG. 1A, the diffusion region 113 and the lower electrode of the light emitting element 130 are electrically connected via the plug 122. In the arrangement shown in FIG. 1A, the lower electrode is an individual electrode arranged for each light emitting element 130. The light emitting layer 131 and the upper electrode 132 are shared by a plurality of light emitting elements 130. Accordingly, the light emitting region of each light emitting element 130 can be decided by the size and shape of the lower electrode, and the position and arrangement interval (to be also referred to as the pixel interval or pixel pitch) of the light emitting element 130 can be decided by the arrangement of the lower electrode.

For example, a light emitting material such as an organic electroluminescence (EL) material can be used for the light emitting layer 131. That is, the light emitting element 130 may be an organic EL element. Alternatively, the light emitting element 130 may be one of elements using various kinds of light emission techniques such as an inorganic EL element, a light emitting diode element, and a laser element, and the light emitting layer 131 corresponding to each element is arranged. The upper electrode 132 can be a transparent electrode that transmits light generated in the light emitting layer 131. For the upper electrode 132, for example, a transparent metal oxide such as indium tin oxide, thin-film silver, a thin-film silver alloy, or the like can be used.

A wiring structure 140 may be connected to the gate electrode 111 and the diffusion region 112 of the transistor 110. The wiring structure 140 includes a wiring pattern 141, a plug 142, and the insulating layer 143. FIG. 1A shows the wiring pattern 141 in one layer, but the wiring pattern may be arranged across a plurality of layers. The wiring pattern 141 and the plug 142 can be formed using, for example, a metal such as copper, tungsten, titanium, or aluminum, or an alloy thereof. A barrier layer using tantalum, tantalum nitride, or the like may be arranged between the insulating layer 143 and each of the wiring pattern 141 and the plug 142. The insulating layer 143 can be formed using, for example, silicon oxide, silicon nitride, silicon oxynitride, or silicon carbide.

The insulating layer 152 is formed on a main surface 153 of the substrate 151 facing the substrate 105. The insulating layer 152 can be formed using, for example, silicon oxide, silicon nitride, silicon oxynitride, or silicon carbide. The insulating layer 143 and the insulating layer 152 are bonded via a bonding surface 154. The insulating layer 143 and the insulating layer 152 can be bonded using, for example, surface activated bonding or the like. Alternatively, a bonding layer using an adhesive agent or the like may be arrange between the insulating layer 143 and the insulating layer 152.

FIG. 1B exemplarily shows a plan view taken along a line A-A′ shown in FIG. 1A. On the other hand, the sectional view shown in FIG. 1A is a sectional view taken along a line B-B′ in FIG. 1B. As shown in FIG. 1B, each of the gate insulating film 114, the diffusion region 112, and the well region 115 is arranged to surround the gate electrode 111.

In the light emitting device 10 as described above, the transistor 110 can cause a current to flow between the diffusion region 112 provided on the main surface 101 side of the substrate 105 and the diffusion region 113 provided on the main surface 102 side. Therefore, a through electrode need not be provided. In other word, the transistor 110 can be arranged instead of arranging a through electrode. As a result, the light emitting element 130 can be arranged at an interval considering the area required for the transistor including the transistor 110 arranged in the main surface 102 of the substrate 105 without considering the area required for a through electrode. As a result, it is possible to increase the density of the light emitting elements 130 and the density of transistors including the transistor 110. Here, as has been described above, in the arrangement shown in FIG. 1A, the arrangement interval of the light emitting element 130 can be defined by the interval of the lower electrode (individual electrode) provided so as to correspond to each light emitting element 130.

A plurality of the transistors 110 can be arranged in the light emitting device 10. In this case, the diffusion regions 112 of the plurality of the transistors 110 are electrically isolated from each other. Similarly, the diffusion regions 113 of the plurality of the transistors 110 are electrically isolated from each other. With this, it is possible to independently drive the plurality of light emitting elements 130 respectively connected to the plurality of the transistors 110.

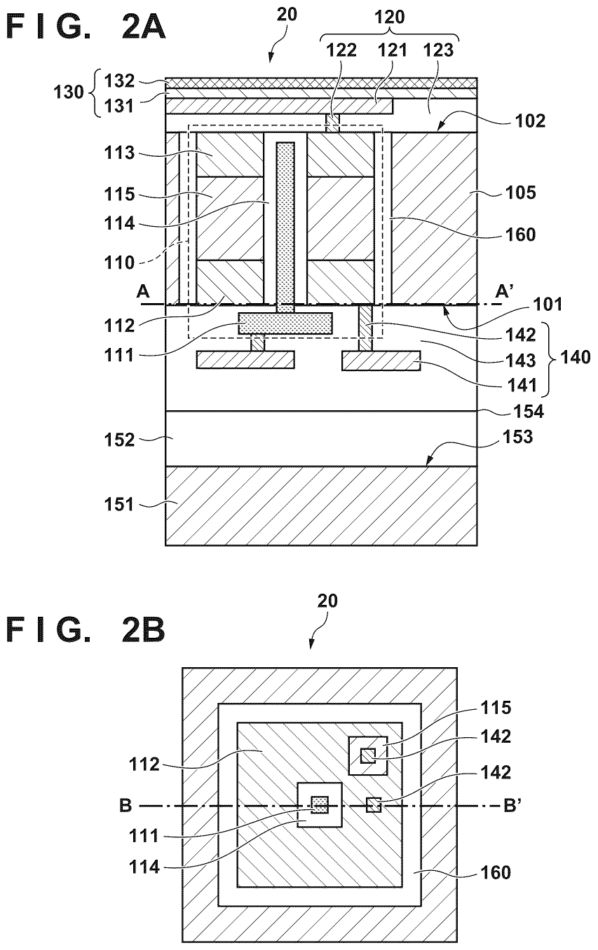

FIG. 2A exemplarily shows a sectional structure of a light emitting device 20 as a modification of the light emitting device 10 shown in FIG. 1A. In addition to the arrangement of the light emitting device 10, an isolation structure 160 is arranged in the light emitting device 20, which is configured to electrically isolate a plurality of transistors 110 arranged in the light emitting device 20 from each other. As shown in FIG. 2A, the isolation structure 160 extends in the direction intersecting the main surface 101 of the substrate 105. The isolation structure 160 may include a dielectric such as silicon oxide or silicon nitride. In other words, a dielectric material may be embedded in the isolation structure 160.

FIG. 2B exemplarily shows a plan view taken along a line A-A′ shown in FIG. 2A. On the other hand, the sectional view shown in FIG. 2A is a sectional view taken along a line B-B′ in FIG. 2B. As shown in FIG. 2B, in an orthogonal projection to the main surface 101 of the substrate 105, the isolation structure 160 may be arranged to surround the transistor 110. Further, as shown in FIG. 2A, the isolation structure 160 may be provided to extend through the substrate 105 from the main surface 101 of the substrate 105 to the main surface 102.

In the light emitting device 20 as described above, the transistor 110 is surrounded by the isolation structure 160, and this can reduce a leakage current since strong element isolation is achieved. In addition, since the isolation structure 160 hinders spread of a depletion layer when a voltage is applied, a parasitic capacitance is reduced, and the transistor 110 can be driven more quickly. Further, the plug 142 is connected to the well region 115 so that the potential of the well region 115 can be controlled.

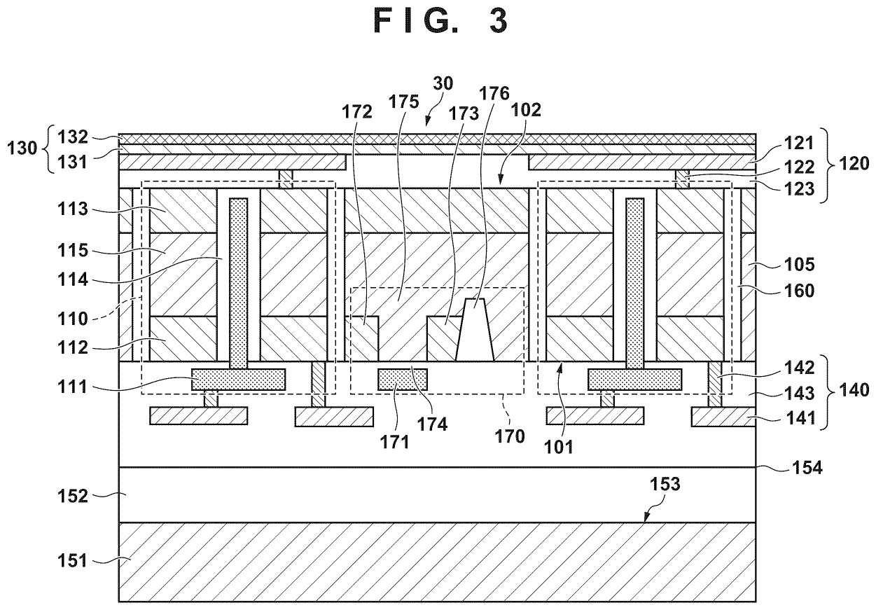

FIG. 3 exemplarily shows the sectional structure of a light emitting device 30 as a modification of the light emitting device 20 shown in FIG. 2A. In addition to the arrangement of the light emitting device 20, a transistor 170 is arranged in the light emitting device 30. The transistor 170 includes a gate electrode 171 arranged along the main surface 101 of the substrate 105, a diffusion region 172 arranged in the main surface 101 of the substrate 105 and functioning as one of a source region and a drain region, and a diffusion region 173 arranged in the main surface 101 of the substrate 105 and functioning as the other of the source region and the drain region. A gate insulating film 174 is arranged between the gate electrode 171 and a well region 175 where a channel region is to be formed. An element isolation structure 176 may be arranged in the outer edge of the transistor 170. Here, the expression “the diffusion regions 172 and 173 arranged in the main surface 101 of the substrate 105” is not limited to a case where the diffusion regions 172 and 173 are exposed as the main surface 101, as in the above description. For example, an insulating layer made of silicon oxide or the like may be arranged on the diffusion regions 172 and 173.

As shown in FIG. 3, not only the transistor 110 in which a channel region where a current flows in the direction intersecting the main surface 101 of the substrate 105 is to be formed, but also the transistor 170 in which a channel region where a current flows in a direction along the main surface 101 is to be formed may be arranged in the substrate 105. With this, the degree of freedom of the circuit arrangement and the circuit layout improves in the light emitting device 30.

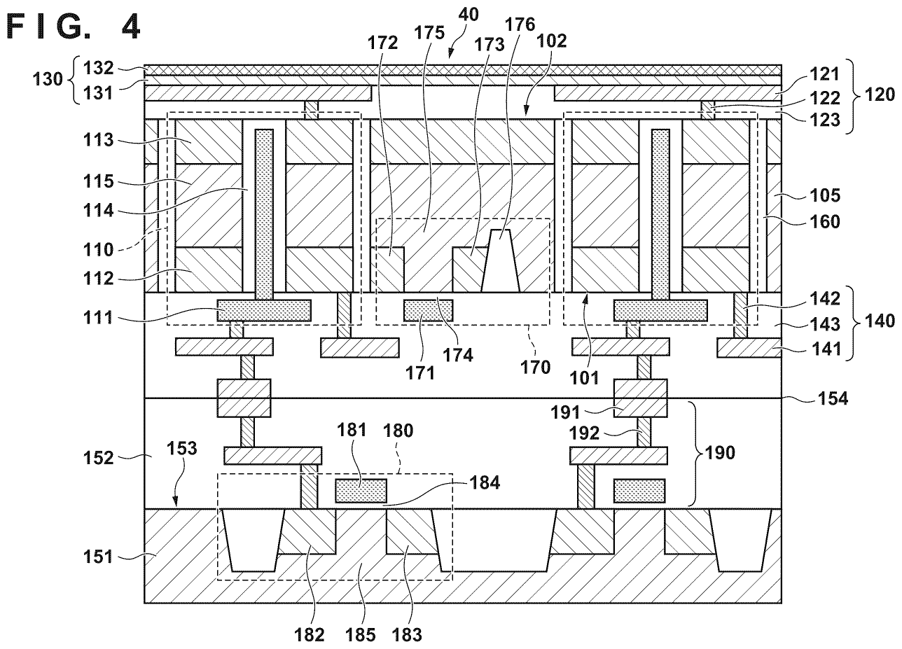

FIG. 4 exemplarily shows the sectional structure of a light emitting device 40 as a modification of the light emitting device 30 shown in FIG. 3. In addition to the arrangement of the light emitting device 30, a transistor 180 and a wiring structure 190 are arranged in the substrate 151 in the light emitting device 40. In a case of arranging the transistor 180 in the substrate 151, the substrate 151 can be a semiconductor substrate using silicon or the like. The transistor 180 includes a gate electrode 181 arranged along the main surface 153 of the substrate 151, a diffusion region 182 arranged in the main surface 153 of the substrate 151 and functioning as one of a source region and a drain region, and a diffusion region 183 arranged in the main surface 153 of the substrate 151 and functioning as the other of the source region and the drain region. A gate insulating film 184 is arranged between the gate electrode and a well region 185 where a channel region is to be formed. An element isolation structure 186 may be arranged in the outer edge of the transistor 180. In this manner, the arrangement of the transistor 180 may be similar to the arrangement of the transistor 170. However, the transistor 170 and the transistor 180 may have different dimensions. For example, the gate insulating film 174 and the gate insulating film 184 may have different thicknesses, or the gate length and gate width may be different. The wiring structure 190 can include a wiring pattern 191 and a plug 192 arranged in the insulating layer 152.

In the light emitting device 40, the transistor 180 is arranged in the substrate 151. The transistor 180 is electrically connected to the substrate 105 via the wiring structure 190. For example, the transistor 180 may be connected to the transistor 110 arranged in the substrate 105 as shown in FIG. 4, or may be connected to the transistor 170. When transistors are arranged not only in the substrate 105 but also in the substrate 151, the number of transistors which can be arranged per the area of the light emitting device 40 increases, and as a result, the densities of various elements can be increased in the light emitting device 40. For example, by distributing transistors connected to one light emitting element 130 between the substrate 105 and the substrate 151, the high density of the light emitting elements 130 can be implemented.

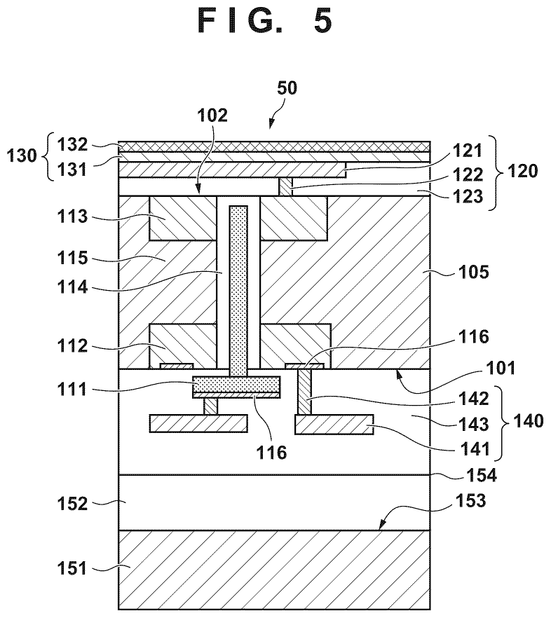

FIG. 5 exemplarily shows the sectional structure of a light emitting device 50 as a modification of the light emitting device 10 shown in FIG. 1A. In addition to the arrangement of the light emitting device 10, a silicide 116 is at least partially arranged in each of the gate electrode 111 and the diffusion region 112 of the transistor 110 in the light emitting device 50. The silicide 116 is made of an alloy of silicon and a metal such as cobalt, nickel, or titanium. Hence, for example, polysilicon or the like can be used for the gate electrode 111. In the light emitting device 50, since the silicide 116 is arranged, a contact resistance between the plug 142 of the wiring structure 140 and the gate electrode 111 or the diffusion region 112 is reduced. As a result, the transistor 110 can be driven more quickly.

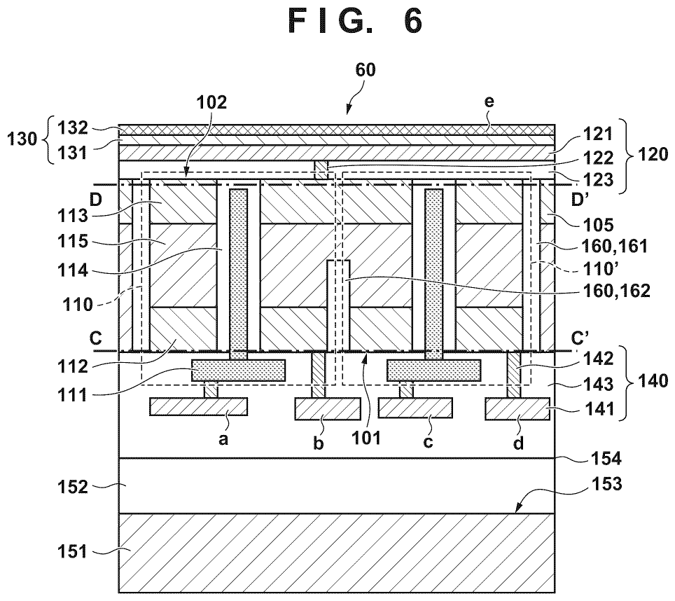

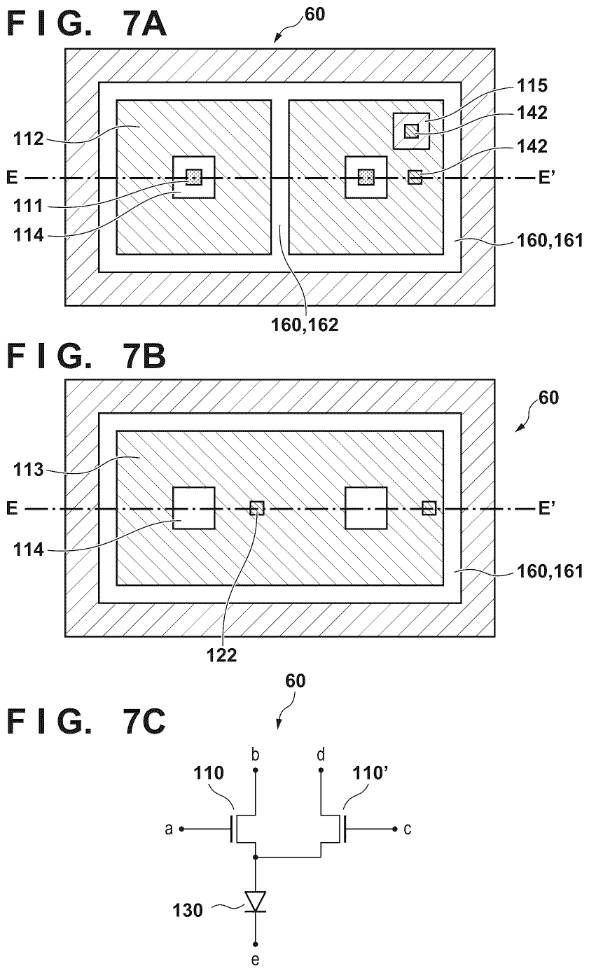

FIG. 6 exemplarily shows the sectional structure of a light emitting device 60 as a modification of the light emitting device 20 shown in FIG. 2A. FIG. 7A exemplarily shows a plan view taken along a line C-C′ shown in FIG. 6. FIG. 7B exemplarily shows a plan view taken along a line D-D′ shown in FIG. 6. On the other hand, the sectional view shown in FIG. 6 is a sectional view taken along a line E-E′ in FIGS. 7A and 7B.

A plurality of transistors including the transistor 110 and a transistor 110′ adjacent to each other shown in FIG. 6 are arranged in the substrate 105. In this case, the diffusion region 112 of the transistor 110 and the diffusion region 112 of the transistor 110′ are electrically isolated from each other. On the other hand, the diffusion region 113 of the transistor 110 and the diffusion region 113 of the transistor 110′ are electrically connected to each other. As shown in FIG. 6, the transistor 110 and the transistor 110′ may share the same diffusion region 113.

The isolation structure 160 extending from the main surface 101 of the substrate 105 to the main surface 102 to electrically isolate the diffusion region 112 of the transistor 110 and the diffusion region 112 of the transistor 110′ from each other is arranged between the diffusion region 112 of the transistor 110 and the diffusion region 112 of the transistor 110′. Unlike the arrangement shown in FIG. 2A, the isolation structure 160 is not arranged between the diffusion region 113 of the transistor 110 and the diffusion region 113 of the transistor 110′. That is, in the light emitting device 60, the isolation structure 160 includes a portion 161 arranged to surround the transistor 110 and the transistor 110′ and a portion 162 arranged between the transistor 110 and the transistor 110′ in the orthogonal projection to the main surface 101 of the substrate 105. In this case, the height of the portion 161 in the direction intersecting the main surface 101 of the substrate 105 is greater than the height of the portion 162 in the direction intersecting the main surface 101 of the substrate 105. With this, the diffusion region 112 of the transistor 110 and the diffusion region 112 of the transistor 110′ are electrically isolated from each other, while the diffusion region 113 of the transistor 110 and the diffusion region 113 of the transistor 110′ are electrically connected to each other. The portion 162 of the isolation structure 160 isolates the diffusion regions 112 of two transistors 110 and 110′ from each other, but the diffusion regions 113 are connected between two transistors 110 and 110′.

As shown in FIG. 6, the portion 162 of the isolation structure 160 is arranged halfway through the well region 115 from the main surface 101 of the substrate 105, but the portion 162 is not limited to this. It is sufficient that the diffusion region 112 of the transistor 110 and the diffusion region 112 of the transistor 110′ can be electrically isolated so, for example, the portion 162 of the isolation structure 160 may not be arranged in the well region 115. Further, for example, it is sufficient that the diffusion region 113 of the transistor 110 and the diffusion region 113 of the transistor 110′ can be electrically connected so that, for example, the portion 162 of the isolation structure 160 may be arranged to be in contact with the diffusion region 113 from the main surface 101 of the substrate 105, or may be arranged halfway through the diffusion region 113.

FIG. 7C shows the circuit arrangement of the light emitting device 60 shown in FIGS. 6, 7A, and 7B. Symbols “a” to “e” shown in FIG. 6 correspond to nodes a to e shown in FIG. 7C, respectively. As shown in FIG. 7C, the light emitting device 60 is formed such that two transistors 110 and 110′ are connected to one light emitting element 130. With this arrangement, for example, it is possible to more easily implement increasing the resolution from no emission (minimum luminosity) to the maximum luminosity while increasing the light emission intensity of the light emitting element 130.

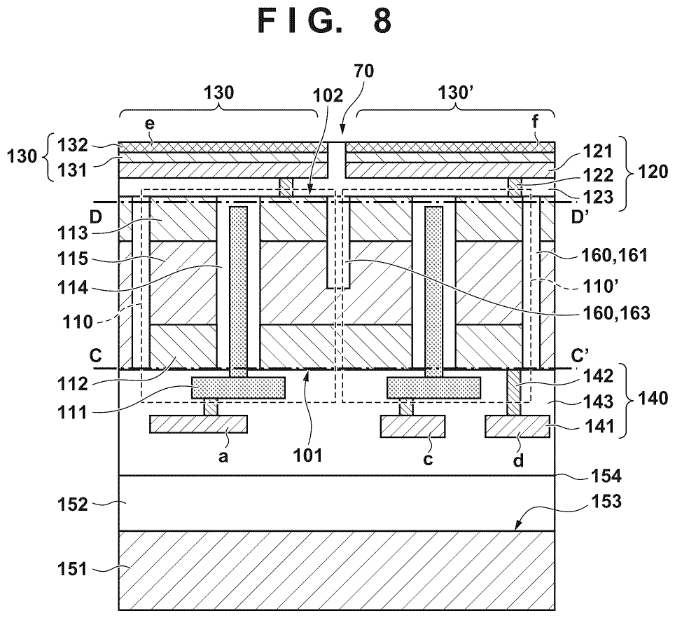

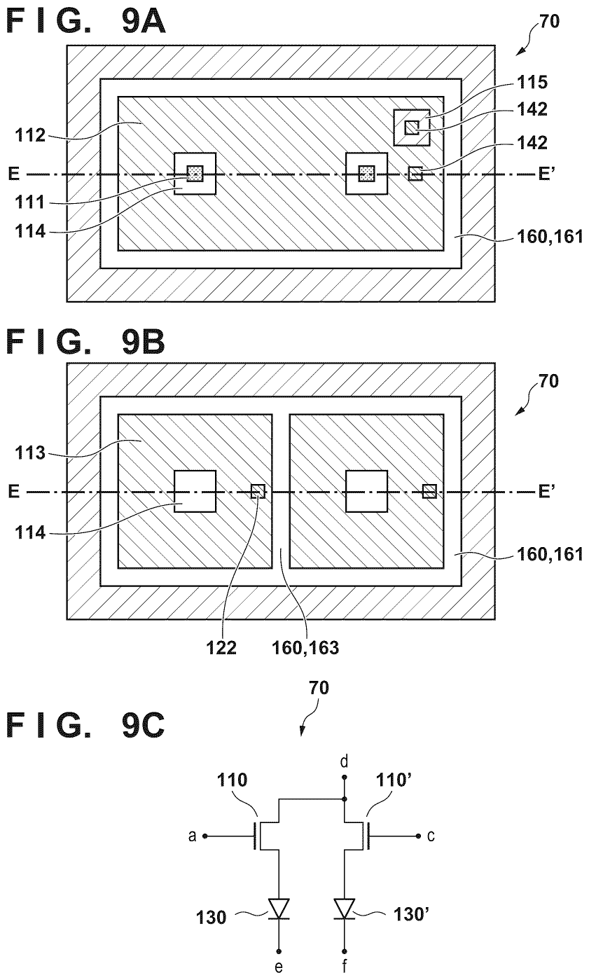

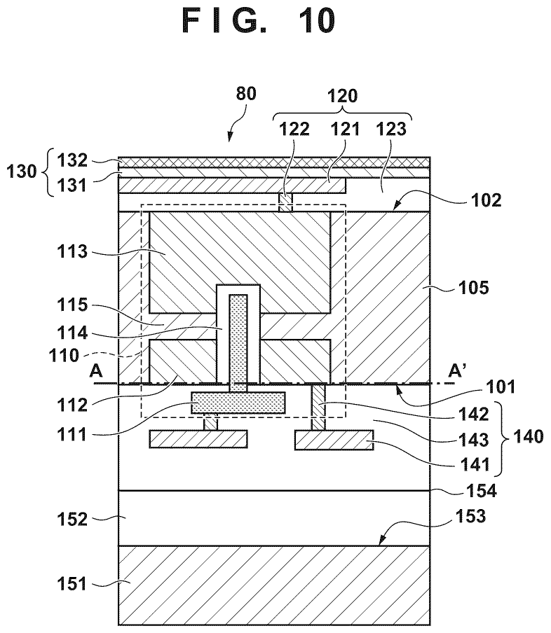

FIG. 8 exemplarily shows the sectional structure of a light emitting device 70 as a modification of the light emitting device 20 shown in FIG. 2A. FIG. 9A exemplarily shows a plan view taken along a line C-C′ shown in FIG. 8. FIG. 9B exemplarily shows a plan view taken along a line D-D′ shown in FIG. 8. On the other hand, the sectional view shown in FIG. 8 is a sectional view taken along a line E-E′ in FIGS. 9A and 9B.

A plurality of transistors 110 including the transistor 110 and the transistor 110′ adjacent to each other shown in FIG. 8 are arranged in the substrate 105. On the main surface 102 of the substrate 105, a plurality of light emitting elements including the light emitting element 130 controlled by the transistor 110 and a light emitting element 130′ controlled by the transistor 110′ are arranged. In this case, the diffusion region 113 of the transistor 110 and the diffusion region 113 of the transistor 110′ are electrically isolated from each other. The different light emitting elements 130 and 130′ are respectively connected to the diffusion region 113 of the transistor 110 and the diffusion region 113 of the transistor 110′ electrically isolated from each other. On the other hand, the diffusion region 112 of the transistor 110 and the diffusion region 112 of the transistor 110′ are electrically connected to each other. As shown in FIG. 8, the transistor 110 and the transistor 110′ may share the same diffusion region 112.

The isolation structure 160 extending from the main surface 102 of the substrate 105 to the main surface 101 to electrically isolate the diffusion region 113 of the transistor 110 and the diffusion region 113 of the transistor 110′ from each other is arranged between the diffusion region 113 of the transistor 110 and the diffusion region 113 of the transistor 110′. Unlike the arrangement shown in FIG. 2A, the isolation structure 160 is not arranged between the diffusion region 112 of the transistor 110 and the diffusion region 112 of the transistor 110′. That is, in the light emitting device 70, the isolation structure 160 includes the portion 161 arranged to surround the transistor 110 and the transistor 110′ and a portion 163 arranged between the transistor 110 and the transistor 110′ in the orthogonal projection to the main surface 101 of the substrate 105. In this case, the height of the portion 161 in the direction intersecting the main surface 101 of the substrate 105 is greater than the height of the portion 163 in the direction intersecting the main surface 101 of the substrate 105. With this, the diffusion region 113 of the transistor 110 and the diffusion region 113 of the transistor 110′ are electrically isolated from each other, while the diffusion region 112 of the transistor 110 and the diffusion region 112 of the transistor 110′ are electrically connected to each other. The portion 163 of the isolation structure 160 isolates the diffusion regions 113 of two transistors 110 and 110′ from each other, but the diffusion regions 112 are connected between two transistors 110 and 110′.

As shown in FIG. 8, the portion 163 of the isolation structure 160 is arranged halfway through the well region 115 from the main surface 102 of the substrate 105, but the portion 163 is not limited to this. It is sufficient that the diffusion region 113 of the transistor 110 and the diffusion region 113 of the transistor 110′ can be electrically isolated so, for example, the portion 163 of the isolation structure 160 may not be arranged in the well region 115. Further, for example, it is sufficient that the diffusion region 112 of the transistor 110 and the diffusion region 112 of the transistor 110′ can be electrically connected so that, for example, the portion 163 of the isolation structure 160 may be arranged to be in contact with the diffusion region 112 from the main surface 102 of the substrate 105, or may be arranged halfway through the diffusion region 112.

FIG. 9C shows the circuit arrangement of the light emitting device 70 shown in FIGS. 8, 9A, and 9B. Symbols “a” and “c” to “f” shown in FIG. 8 correspond to nodes a and c to f shown in FIG. 9C, respectively. As shown in FIG. 9C, the light emitting device 70 can supply power to two light emitting elements 130 and 130′ from one node d. That is, the circuit arrangement can be simplified.

FIG. 10 exemplarily shows the sectional structure of a light emitting device 80 as a modification of the light emitting device 10 shown in FIG. 1A. In the light emitting device 10 shown in FIG. 1A, the gate electrode 111 reaches near the main surface 102 of the substrate 105, and the gate insulating film 114 is provided to extend through the substrate 105 from the main surface 101 of the substrate 105 to the main surface 102. On the other hand, in the light emitting device 80 shown in FIG. 10, the gate electrode 111 is formed from the main surface 101 of the substrate 105 to the inside of the diffusion region 113 arranged on the main surface 102 side. The gate insulating film 114 is also formed from the main surface 101 of the substrate 105 to the inside of the diffusion region 113 arranged on the main surface 102 side, without extending through the substrate 105. Also in the arrangement shown in FIG. 10, when a voltage is applied to the gate electrode 111, a channel region for flowing a current between the diffusion region 112 and the diffusion region 113 is formed near the interface between the well region 115 and the gate insulating film 114. That is, also in the light emitting device 80, the transistor 110 functions as a switch element.

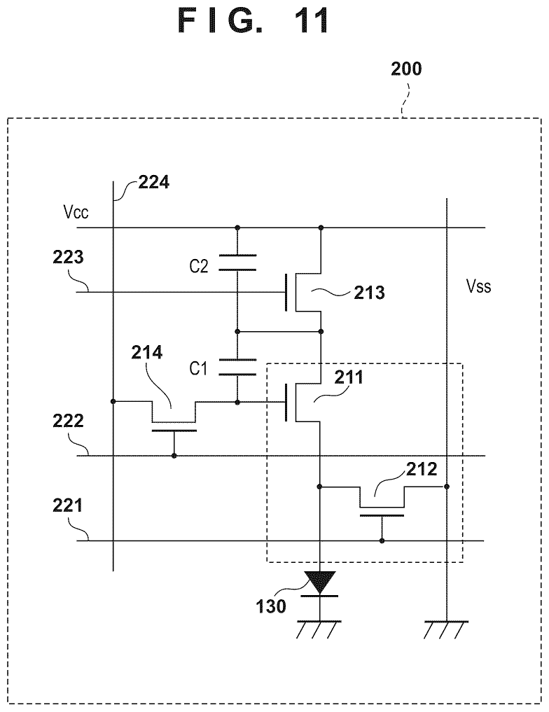

FIG. 11 is a view showing an arrangement example of a pixel circuit 200 configured to drive and control one light emitting element 130. In FIG. 11, the above-described transistor 110 corresponds to, for example, a transistor 211. The drain region of the transistor 211 and the source region of a transistor 212 are connected to the light emitting element 130. The drain region of the transistor 211 may correspond to the above-described diffusion region 113. A transistor 214 is connected to the gate electrode of the transistor 211. The gate electrode of the transistor 211 may correspond to the above-described gate electrode 111. A transistor 213 is connected to the source region of the transistor 211. The source region of the transistor 211 may correspond to the above-described diffusion region 112. A capacitive element C1 is connected between the gate electrode and source region of the transistor 211, and a capacitive element C2 is connected between the source region of the transistor 211 and a power supply line Vcc.

The transistor 214 is controlled via a signal line 222. When the transistor 214 is set in an ON state, the voltage value (luminance signal) of a signal line 224 is written in the gate electrode of the transistor 211. The transistor 213 is controlled via a signal line 223. When the transistor 213 is set in an ON state, a current corresponding to the voltage value (luminance signal) written in the gate electrode of the transistor 211 flows to the light emitting element 130 from the power supply line Vcc via the transistor 213 and the transistor 211. This causes the light emitting element 130 to emit light with the light amount corresponding to the luminance signal. The switching operation of the transistor 213 can provide a period (non-light emission period) during which the light emitting element 130 is set in a non-light emission state, and control the ratio between the light emission period and the non-light emission period of the light emitting element 130 (so-called duty control). The duty control can reduce afterimage blurring accompanying light emission from the pixel over a period of one frame. Therefore, it is possible to further improve image quality especially when displaying a moving image. The transistor 212 is controlled via a signal line 221. The potential of a power supply line Vss to which the drain region of the transistor 212 is connected is set such that, when the transistor 212 is set in an ON state, no current flows to the light emitting element 130 so the light emitting element 130 does not emit light. The transistor 211 can also be called a driving transistor or the like. The transistor 214 can also be called a selection transistor, a write transistor, or the like. The transistor 213 can also be called a light emission control transistor or the like. The transistor 212 can also be called a reset transistor or the like.

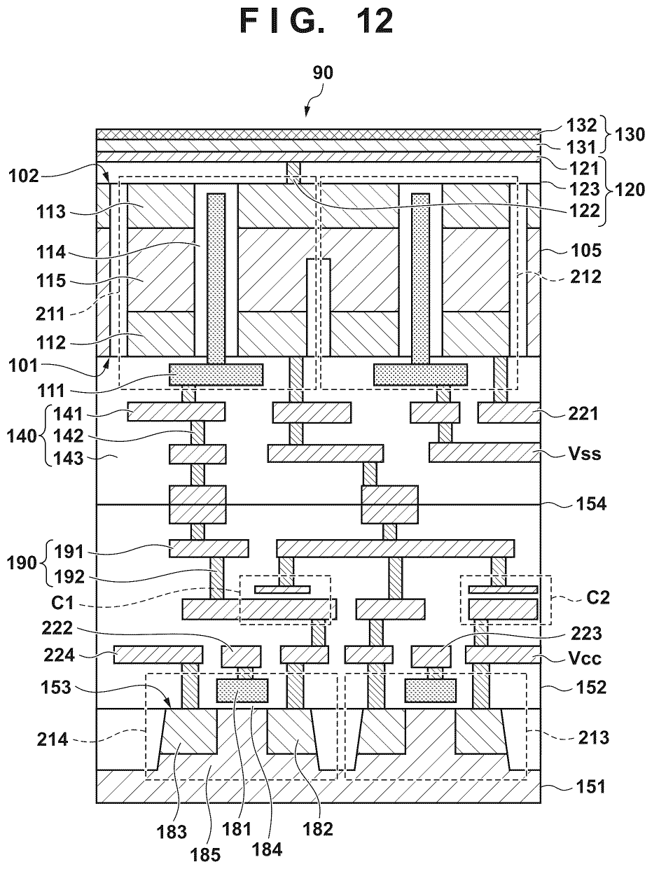

In the pixel circuit 200 shown in FIG. 11, a higher voltage may be applied to the transistor 211 and the transistor 212 connected to the light emitting element 130 than the transistor 214 and the transistor 213. FIG. 12 exemplarily shows the sectional structure of a light emitting device 90 that implements the pixel circuit 200 shown in FIG. 11. The arrangement shown in FIG. 12 can also be referred to as a modification of the light emitting device 40 shown in FIG. 4 in which transistors connected to one light emitting element 130 are distributed between the substrate 105 and the substrate 151.

In this embodiment, the transistor 211 and the transistor 212 are formed in the substrate 105. The transistor 213 and the transistor 214 are formed in the substrate 151. That is, the transistors 211 to 214 are formed in different substrates 105 and 151 in accordance with the voltages applied to the transistors 211 to 214. For example, the design value of the breakdown voltage may be different between the transistors 211 and 212 and the transistors 213 and 214. For example, the transistor 211 and the transistor 212 may have the same design value of the breakdown voltage. Similarly, the transistor 213 and the transistor 214 may have the same design value of the breakdown voltage. Here, as shown in FIG. 12, the transistor 211 and the transistor 212 may have the same structure as the above-described transistor 110. Further, as shown in FIG. 12, the transistor 213 and the transistor 214 may have the same structure as the above-described transistor 180.

Here, the arrangement of the transistors 211 to 214 is not limited to the arrangement shown in FIG. 12. For example, at least one of the transistor 213 and the transistor 214 may be arranged in the substrate 105. For example, the transistors 211 to 214 included in the pixel circuit 200 for driving one light emitting element 130 may be arranged in one substrate 105. In the arrangement shown in FIG. 12, the capacitive elements C1 and C2 are arranged in the wiring structure 190 provided on the substrate 151, but the capacitive elements C1 and C2 are not limited to this and can be arranged in the wiring structure 140 provided on the substrate 105.

In any of the arrangements of the light emitting devices 10 to 90 described above, the transistor 110 controls the light emitting element 130. In other words, the transistor 110 has a function of supplying power for driving the light emitting element 130. Accordingly, a high electric field may be applied near the diffusion region 112. Therefore, the thickness of a certain portion of the gate insulating film 114 of the transistor 110 may be larger than the thickness of the other portion between the certain portion and the main surface 102 of the substrate 105. For example, the thickness of the gate insulating film 114 may decrease stepwise or continuously from the main surface 101 of the substrate 105 toward the main surface 102. By making the film thickness of the gate insulating film 114 of the transistor 110 larger on the diffusion region 112 side than on the diffusion region 113 side, the transistor 110 that withstands application of a high electric field can be implemented. When the thickness of the gate insulating film 114 of the transistor 110 is large on the diffusion region 112 side, the reliability of each of the light emitting devices 10 to 70 can improve.

A manufacturing method of manufacturing the above-described light emitting devices 10 to 90 will be described. When manufacturing the light emitting devices 10 to 90, the following steps may be included. For example, when forming the substrate 105, a SIO (Silicon On Insulator) substrate may first be prepared. After elements including the transistor 110 in the substrate 105 and the wiring structure 140 are formed, the substrate 105 is bonded to the substrate 151. Then, the substrate 105 is thinned by polishing to a desired film thickness of the substrate 105. At this time, if an SOI substrate is used as the substrate 105, by performing polishing up to the insulating layer (for example, silicon oxide layer) of the SOI substrate, the substrate 105 can be uniformly polished with relative ease. That is, polishing is performed from the side of the SOI substrate where the transistor 110 and the like are not formed, and the surface of the SOI substrate polished in the polishing step serves as the main surface 102 of the substrate 105. This can suppress the variation of the film thickness of the thinned substrate 105. As a result, the characteristic variation of the transistor 110 where a current flows along the film thickness direction of the substrate 105 (the direction intersecting the main surface 101 of the substrate 105) is suppressed.

Alternatively, a so-called epitaxial substrate including a first layer having a high impurity concentration and a second layer epitaxially grown on the first layer and having a lower impurity concentration than the first layer may be used as the substrate 105. In this case, the epitaxial substrate may be an SOI substrate including a third layer having an appropriate impurity concentration and an insulating layer arranged between the third layer and the first layer. That is, the epitaxial substrate may be an SOI substrate having a stacked structure of the second layer having a low impurity concentration/the first layer having a high impurity concentration/an insulating layer/the third layer having an appropriate impurity concentration.

A part of the first layer doped with impurities at a high concentration is made to function as the diffusion region 113, and a part of the second layer doped with impurities at a low concentration is made to function as the well region 115. With this, a step of processing the diffusion region 113 and the well region 115 can be omitted. In addition, if the epitaxial substrate is the SOI substrate as described above, by performing polishing from the side of the third layer, the thickness variation of the thinned substrate 105 is suppressed.

The embodiments described above may be combined or partially omitted. For example, the silicide 116 arranged in the light emitting device 50 shown in FIG. 5 may be arranged in the light emitting devices 10 to 40, 60, and 70. Alternatively, for example, the transistor 170 may not be arranged in the light emitting device 40 shown in FIG. 4. Other constituent elements can also be selected as appropriate.

Application examples in which any of the light emitting devices 10 to 90 according to this embodiment including a light emitting element such as an organic EL element arranged therein is applied to a display device, a photoelectric conversion device, an electronic apparatus, an illumination device, a moving body, and a wearable device will be described here with reference to FIGS. 13 to 19A and 19B. Details of the components of the above-described light emitting devices 10 to 90 and modifications will be described first, and the application examples will be described after that. The description will be given here assuming that the light emitting layer 131 is an organic EL layer.

### Arrangement of Organic Light Emitting Element

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer can be provided between the protection layer and the color filter. The planarizing layer can be made of acrylic resin or the like. The same applies to a case in which a planarizing layer is provided between the color filter and the microlens.

### Substrate

Quartz, glass, a silicon wafer, a resin, a metal, or the like may be used as a substrate. Furthermore, a switching element such as a transistor and a wiring may be provided on the substrate, and an insulating layer may be provided thereon. The insulating layer may be made of any material as long as a contact hole can be formed so that the wiring can be formed between the insulating layer and the first electrode and insulation from the unconnected wiring can be ensured. For example, a resin such as polyimide, silicon oxide, silicon nitride, or the like can be used.

### Electrode

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a work function as large as possible may be used. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used.

One of these electrode materials may be used singly, or two or more of them may be used in combination. The anode may be formed by a single layer or a plurality of layers.

If the anode is used as a reflective electrode, for example, chromium, aluminum, silver, titanium, tungsten, molybdenum, an alloy thereof, a stacked layer thereof, or the like can be used. The above materials can function as a reflective film having no role as an electrode. If the anode is used as a transparent electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function may be used. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Among others, silver may be used. To suppress aggregation of silver, a silver alloy is more suitable for use. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but direct current sputtering or alternating current sputtering is suitable since the good film coverage is provided and the resistance is easily lowered.

### Pixel Isolation Layer

A pixel isolation layer is formed by a silicon nitride (SiN) film, a silicon oxynitride (SiON) film, or a silicon oxide (SiO) film formed using a Chemical Vapor Deposition method (CVD method). To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, it is suitable to adjust the taper angle of the side wall of the pixel isolation layer or the film thickness of the pixel isolation layer to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by generation of a dark spot or occurrence of a conduction failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer is desirably 10 nm (inclusive) to 150 nm (inclusive). A similar effect can be obtained in an arrangement including only pixel electrodes without the pixel isolation layer. However, in this case, the film thickness of the pixel electrode may be set to be equal to or smaller than half the film thickness of the organic layer or the end portion of the pixel electrode may be formed to have a forward tapered shape of less than 60° because short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer can be arranged between the first and second electrodes, and may be arranged in contact with the first and second electrodes.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation film made of silicon nitride or the like may be provided on the cathode to suppress permeation of water or the like into the organic compound layer. For example, the protection layer can be formed by forming the cathode, transferring it to another chamber without breaking the vacuum, and forming a silicon nitride film having a thickness of 2 μm by a CVD method. The protection layer may be provided using an atomic deposition method (ALD method) after deposition using the CVD method. The material of the film by the ALD method is not limited but can be silicon nitride, silicon oxide, aluminum oxide, or the like. A silicon nitride film may further be formed by the CVD method on the film formed by the ALD method. The film formed by the ALD method may have a film thickness smaller than that of the film formed by the CVD method. More specifically, the film thickness of the film formed by the ALD method may be 50% or less, or 10% or less.

### Color Filter

A color filter may be provided on the protection layer. For example, a color filter considering the size of the organic light emitting element may be provided on another substrate, and this substrate may be bonded to the substrate with the organic light emitting element provided thereon. Alternatively, a color filter may be patterned on the above-described protection layer using a photolithography technique. The color filter can be formed from a polymeric material.

### Planarizing Layer

A planarizing layer may be provided between the color filter and the protection layer. The planarizing layer is provided to reduce unevenness of the lower layer. The planarizing layer may be called a material resin layer without limiting the purpose of the layer. The planarizing layer can be formed from an organic compound, and can be made of a low-molecular material or a polymeric material. However, a polymetric material is more suitable.

The planarizing layers may be provided above and below the color filter, and the same or different materials may be used for them. More specifically, examples of the material include polyvinyl carbazole resin, polycarbonate resin, polyester resin, ABS resin, acrylic resin, polyimide resin, phenol resin, epoxy resin, silicone resin, and urea resin.

### Microlens

The organic light emitting device can include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface may be arranged on the functional layer side of the first surface. For this arrangement, the microlens needs to be formed on the light emitting device. If the functional layer is an organic layer, it is better to avoid a process which produces high temperature in the manufacturing step. In addition, if it is configured to arrange the second surface on the functional layer side of the first surface, all the glass transition temperatures of an organic compound forming the organic layer may be 100° C. or more, and even 130° C. or more.

### Counter Substrate

A counter substrate can be provided on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present invention is formed by the method to be described below.

The organic compound layer forming the organic light emitting element according to the embodiment of the present invention can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes a plurality of pixels. Each pixel includes sub-pixels that emit light components of different colors. The sub-pixels include, for example, R, G, and B emission colors, respectively.

In each pixel, a region also called a pixel opening emits light. This region is the same as the first region. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4μ m.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

### Application of Organic Light Emitting Element of Embodiment of Present Invention

The organic light emitting element according to an embodiment of the present invention can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

With reference to FIGS. 13 to 19A and 19B, application examples of the light emitting devices 10 to 90 will be described below in detail.

FIG. 13 is a schematic view showing an example of the display device using the light emitting devices 10 to 90 of this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. Even when the display device 1000 is a portable apparatus, the battery 1008 need not be provided at this position. The light emitting devices 10 to 90 can be applied to the display panel 1005. Each of the light emitting devices 10 to 90 functioning as the display panel 1005 operates in a state in which it is connected to the active elements such as transistors arranged on the circuit board 1007.

The display device 1000 shown in FIG. 13 can be used for a display unit of a photoelectric conversion device (image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

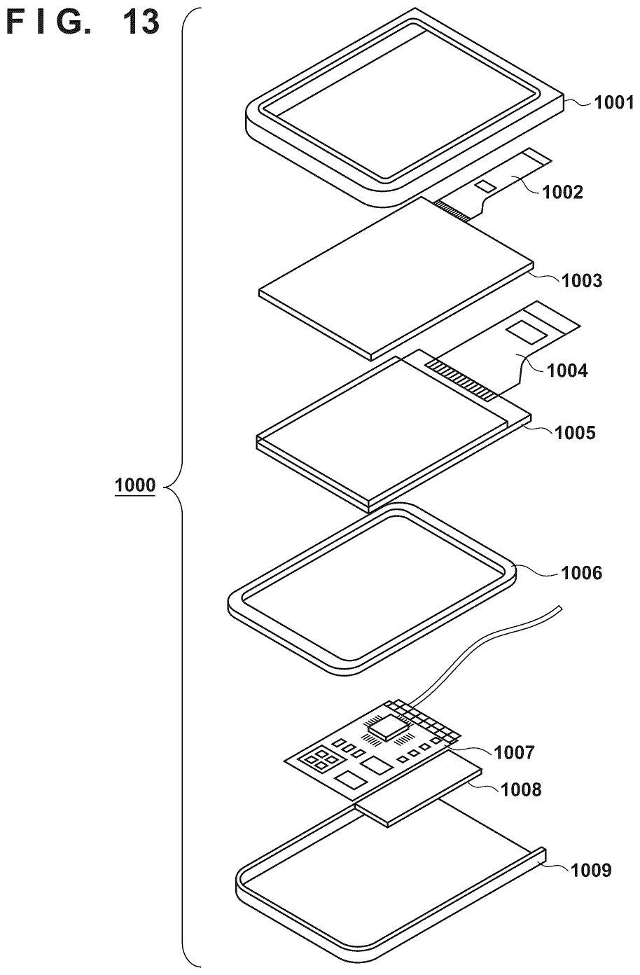

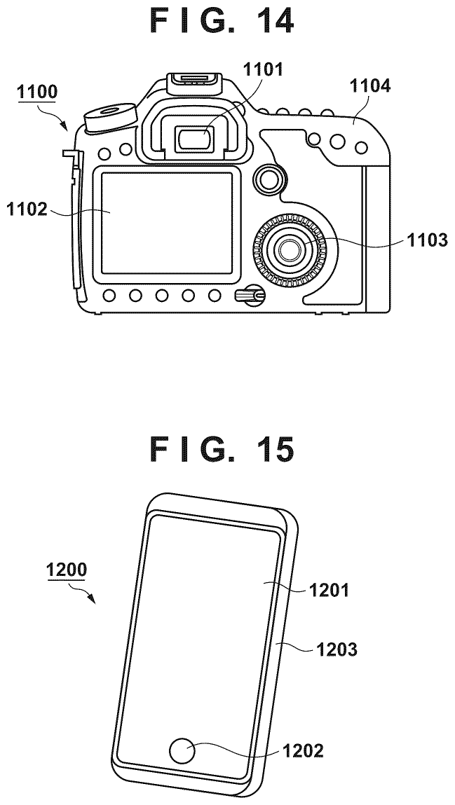

FIG. 14 is a schematic view showing an example of the photoelectric conversion device using the light emitting devices 10 to 90 of this embodiment. A photoelectric conversion device 1100 can include a viewfinder 1101, a rear display 1102, an operation unit 1103, and a housing 1104. The photoelectric conversion device 1100 can also be called an image capturing device. The light emitting devices 10 to 90 according to this embodiment can be applied to the viewfinder 1101 or the rear display 1102 as a display unit. In this case, the light emitting devices 10 to 90 can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time in many cases, so the information should be displayed as soon as possible. Therefore, the light emitting devices 10 to 90 in which a pixel using an organic light emitting material such as an organic EL element is arranged in the display region may be used for the viewfinder 1101 or the rear display 1102. This is so because the organic light emitting material has a high response speed. The light emitting devices 10 to 90 using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting devices 10 to 90 may be applied to a display unit of an electronic apparatus. At this time, the display unit can have both a display function and an operation function. Examples of the portable terminal are a portable phone such as a smartphone, a tablet, and a head mounted display.

FIG. 15 is a schematic view showing an example of an electronic apparatus using the light emitting devices 10 to 90 of this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting devices 10 to 90 according to this embodiment can be applied to the display unit 1201.

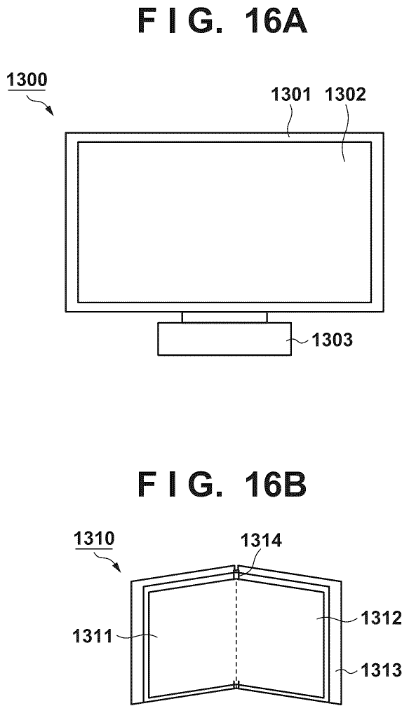

FIGS. 16A and 16B are schematic views showing examples of the display device using the light emitting devices 10 to 90 of this embodiment. FIG. 16A shows a display device such as a television monitor or a PC monitor. A display device 1300 includes a frame 1301 and a display unit 1302. The light emitting devices 10 to 90 according to this embodiment can be applied to the display unit 1302. The display device 1300 can include a base 1303 that supports the frame 1301 and the display unit 1302. The base 1303 is not limited to the form shown in FIG. 16A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 16B is a schematic view showing another example of the display device using the light emitting devices 10 to 90 of this embodiment. A display device 1310 shown in FIG. 16B can be folded, and is a so-called foldable display device. The display device 1310 includes a first display unit 1311, a second display unit 1312, a housing 1313, and a bending point 1314. The light emitting devices 10 to 90 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

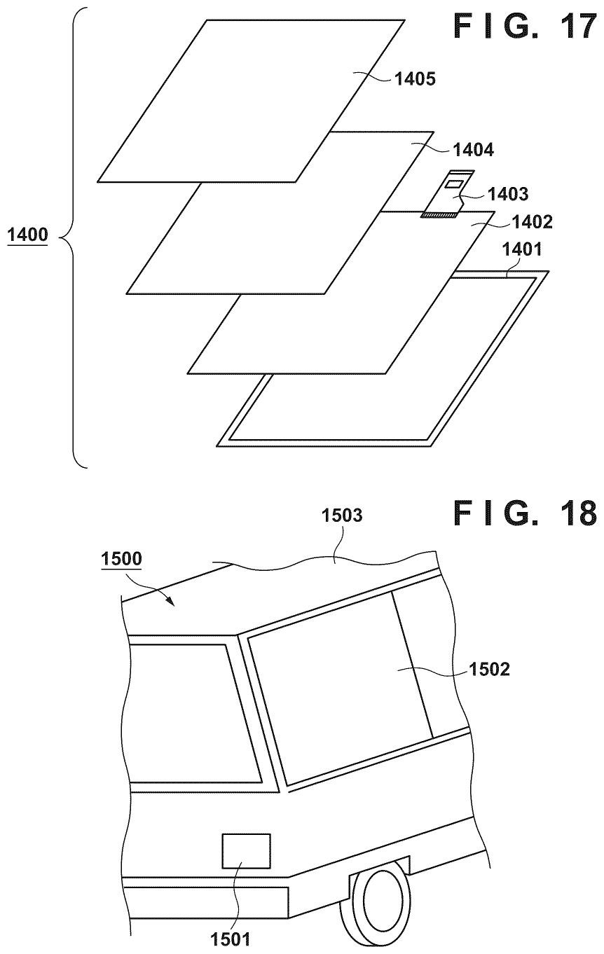

FIG. 17 is a schematic view showing an example of the illumination device using the light emitting devices 10 to 90 of this embodiment. An illumination device 1400 can include a housing 1401, a light source 1402, a circuit board 1403, an optical film 1404, and a light diffusing unit 1405. The light emitting devices 10 to 90 according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination device can also include a cover on the outermost portion, as needed. The illumination device 1400 can include both or one of the optical film 1404 and the light diffusing unit 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to any of the light emitting devices 10 to 90 functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicon.

FIG. 18 is a schematic view of an automobile having a taillight as an example of a vehicle lighting appliance using the light emitting devices 10 to 90 of this embodiment. An automobile 1500 has a taillight 1501, and can have a form in which the taillight 1501 is turned on when performing a braking operation or the like. The light emitting devices 10 to 90 of this embodiment can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting devices 10 to 90 according to this embodiment can be applied to the taillight 1501. The taillight 1501 can include a protection member for protecting any of the light emitting devices 10 to 90 functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display. For this transparent display, the light emitting devices 10 to 90 according to this embodiment may be used. In this case, the constituent materials of the electrodes and the like of the light emitting devices 10 to 90 are formed by transparent members.

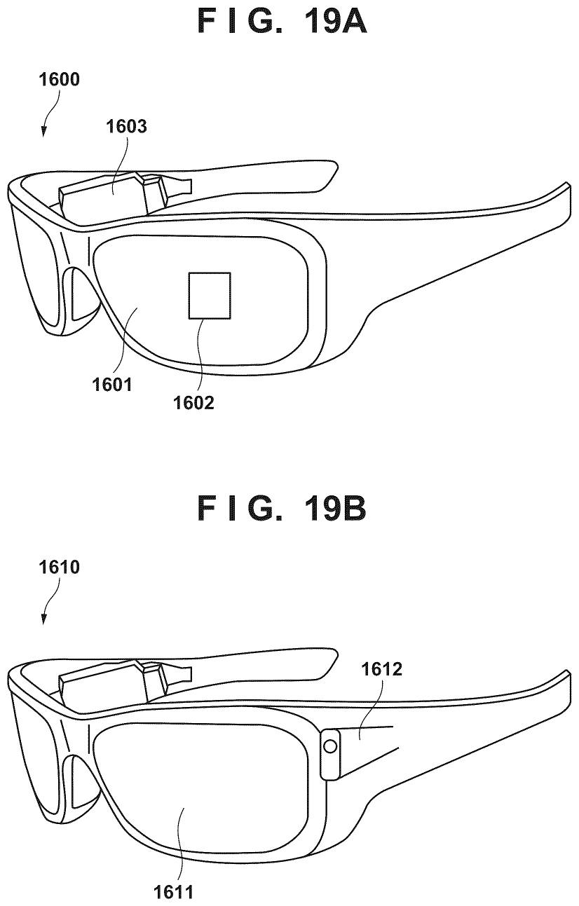

Further application examples of the light emitting devices 10 to 90 according to this embodiment will be described with reference to FIGS. 19A and 19B. The light emitting devices 10 to 90 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 19A. An image capturing device 1602 such as a CMOS sensor or an SPAD is provided on the surface side of a lens 1601 of the glasses 1600. In addition, any of the light emitting devices 10 to 90 according to this embodiment is provided on the back surface side of the lens 1601.

The glasses 1600 further include a control device 1603. The control device 1603 functions as a power supply that supplies electric power to the image capturing device 1602 and the light emitting devices 10 to 90 according to each embodiment. In addition, the control device 1603 controls the operations of the image capturing device 1602 and the light emitting devices 10 to 90. An optical system configured to condense light to the image capturing device 1602 is formed on the lens 1601.

Glasses 1610 (smartglasses) according to one application example will be described with reference to FIG. 19B. The glasses 1610 include a control device 1612, and an image capturing device corresponding to the image capturing device 1602 and any of the light emitting devices 10 to 90 are mounted on the control device 1612. The image capturing device in the control device 1612 and an optical system configured to project light emitted from the light emitting devices 10 to 90 are formed in a lens 1611, and an image is projected to the lens 1611. The control device 1612 functions as a power supply that supplies electric power to the image capturing device and the light emitting devices 10 to 90, and controls the operations of the image capturing device and the light emitting devices 10 to 90. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting devices 10 to 90 according to the embodiment of the present invention can include an image capturing device including a light receiving element, and control a displayed image based on the line-of-sight information of the user from the image capturing device.

More specifically, the light emitting devices 10 to 90 decide a first visual field region at which the user is gazing and a second visual field region other than the first visual field region based on the line-of-sight information. The first visual field region and the second visual field region may be decided by the control device of the light emitting devices 10 to 90, or those decided by an external control device may be received. In the display region of the light emitting devices 10 to 90, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting devices 10 to 90, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting devices 10 to 90, the image capturing device, or an external device. If the external device holds the AI program, it is transmitted to the light emitting devices 10 to 90 via communication.

When performing display control based on line-of-sight detection, smartglasses further including an image capturing device configured to capture the outside can be applied. The smartglasses can display captured outside information in real time.

According to the present invention, a technique advantageous in increasing the density can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A light emitting device comprising a first substrate that includes a first main surface and a second main surface on which a light emitting element is arranged, and a second substrate bonded to the first main surface, wherein
a transistor configured to control the light emitting element is arranged in the first substrate,
the transistor includes a gate electrode extending in a direction intersecting the first main surface, a first diffusion region arranged in the first main surface and functioning as one of a source region and a drain region, and a second diffusion region arranged in the second main surface and functioning as another of the source region and the drain region, and
the first diffusion region and the second diffusion region are arranged in the intersecting direction.

2. The light emitting device according to claim 1, wherein the second diffusion region and the light emitting element are electrically connected.

3. The light emitting device according to claim 1, wherein
a plurality of the transistors are arranged in the first substrate,
the first diffusion regions of the plurality of the transistors are electrically isolated from each other, and
the second diffusion regions of the plurality of the transistors are electrically isolated from each other.

4. The light emitting device according to claim 3, wherein
an isolation structure extending in the intersecting direction to electrically isolate the plurality of the transistors is further arranged in the first substrate, and
in an orthogonal projection to the first main surface, the isolation structure is arranged to surround the transistor.

5. The light emitting device according to claim 4, wherein the isolation structure includes a dielectric.

6. The light emitting device according to claim 4, wherein the isolation structure is provided to extend through the first substrate from the first main surface to the second main surface.

7. The light emitting device according to claim 1, wherein
a plurality of the transistors including a first transistor and a second transistor adjacent to each other are arranged in the first substrate,
the first diffusion region of the first transistor and the first diffusion region of the second transistor are electrically isolated from each other, and
the second diffusion region of the first transistor and the second diffusion region of the second transistor are electrically connected to each other.

8. The light emitting device according to claim 7, wherein an isolation structure extending from the first main surface toward the second main surface to electrically isolate the first diffusion region of the first transistor and the first diffusion region of the second transistor from each other is further arranged between the first diffusion region of the first transistor and the first diffusion region of the second transistor.

9. The light emitting device according to claim 8, wherein the isolation structure is not arranged between the second diffusion region of the first transistor and the second diffusion region of the second transistor.

10. The light emitting device according to claim 8, wherein
in an orthogonal projection to the first main surface, the isolation structure includes a first portion arranged to surround the first transistor and the second transistor, and a second portion arranged between the first transistor and the second transistor, and
a height of the first portion in the intersecting direction is greater than a height of the second portion in the intersecting direction.

11. The light emitting device according to claim 1, wherein
a plurality of the transistors including a first transistor and a second transistor adjacent to each other are arranged in the first substrate,
a plurality of the light emitting elements including a first light emitting element controlled by the first transistor and a second light emitting element controlled by the second transistor are arranged on the second main surface,
the first diffusion region of the first transistor and the first diffusion region of the second transistor are electrically connected to each other, and
the second diffusion region of the first transistor and the second diffusion region of the second transistor are electrically isolated from each other.

12. The light emitting device according to claim 11, wherein an isolation structure extending from the second main surface toward the first main surface to electrically isolate the second diffusion region of the first transistor and the second diffusion region of the second transistor from each other is further arranged between the second diffusion region of the first transistor and the second diffusion region of the second transistor.

13. The light emitting device according to claim 12, wherein the isolation structure is not arranged between the first diffusion region of the first transistor and the first diffusion region of the second transistor.

14. The light emitting device according to claim 12, wherein
in an orthogonal projection to the first main surface, the isolation structure includes a first portion arranged to surround the first transistor and the second transistor, and a second portion arranged between the first transistor and the second transistor, and
a height of the first portion in the intersecting direction is greater than a height of the second portion in the intersecting direction.

15. The light emitting device according to claim 1, wherein a silicide is at least partially arranged in the gate electrode and the first diffusion region.

16. The light emitting device according to claim 1, further comprising a fourth transistor while using the transistor as a third transistor,
wherein the fourth transistor includes a gate electrode arranged along the first main surface, a third diffusion region arranged in the first main surface and functioning as one of a source region and a drain region, and a fourth diffusion region arranged in the first main surface and functioning as another of the source region and the drain region.

17. The light emitting device according to claim 1, further comprising a fifth transistor arranged in the second substrate while using the transistor as a third transistor,
wherein the fifth transistor is electrically connected to the first substrate.

18. The light emitting device according to claim 17, wherein the fifth transistor is connected to the third transistor.

19. The light emitting device according to claim 17, wherein the third transistor and the fifth transistor have different breakdown voltages.

20. The light emitting device according to claim 1, wherein
a thickness of a third portion of a gate insulating film of the transistor is greater than a thickness of a fourth portion between the third portion and the second main surface.

21. The light emitting device according to claim 1, wherein a gate insulating film of the transistor is provided to extend through the first substrate from the first main surface to the second main surface.

22. The light emitting device according to claim 1, wherein a gate insulating film of the transistor is arranged from the first main surface to an inside of the second diffusion region.

23. A display device comprising:
a light emitting device according to claim 1; and
an active element connected to the light emitting device.

24. A photoelectric conversion device comprising:
an optical unit including a plurality of lenses;
an image sensor configured to receive light having passed through the optical unit; and
a display unit configured to display an image,
wherein the display unit displays an image captured by the image sensor, and includes a light emitting device according to claim 1.

25. An electronic apparatus comprising:
a housing provided with a display unit; and
a communication unit provided in the housing and configured to perform external communication,
wherein the display unit includes a light emitting device according to claim 1.

26. A manufacturing method of a light emitting device including a first substrate that includes a first main surface and a second main surface on which a light emitting element is arranged, and a second substrate bonded to the first main surface, wherein
a transistor configured to control the light emitting element is arranged in the first substrate,
the transistor includes a gate electrode extending in a direction intersecting the first main surface, a first diffusion region arranged in the first main surface and functioning as one of a source region and a drain region, and a second diffusion region arranged in the second main surface and functioning as another of the source region and the drain region,
the first diffusion region and the second diffusion region are arranged in the intersecting direction,
the method comprises:
a step of preparing an SOI substrate as the first substrate; and
a polishing step of polishing the SOI substrate, and
the second main surface is a surface of the SOI substrate polished in the polishing step.

27. A manufacturing method of a light emitting device including a first substrate that includes a first main surface and a second main surface on which a light emitting element is arranged, and a second substrate bonded to the first main surface, wherein
a transistor configured to control the light emitting element is arranged in the first substrate,
the transistor includes a gate electrode extending in a direction intersecting the first main surface, a first diffusion region arranged in the first main surface and functioning as one of a source region and a drain region, and a second diffusion region arranged in the second main surface and functioning as another of the source region and the drain region,
the first diffusion region and the second diffusion region are arranged in the intersecting direction,
the method comprises a step of preparing, as the first substrate, an epitaxial substrate including a first layer and a second layer epitaxially grown on the first layer and having a lower impurity concentration than the first layer,
a part of the first layer functions as the first diffusion region, and
a part of the second layer functions as a well region between the first diffusion region and the second diffusion region.

28. The manufacturing method according to claim 27, wherein
the epitaxial substrate is an SOI substrate including a third layer and an insulating layer arranged between the third layer and the first layer,
the first layer is arranged between the second layer and the insulating layer,
the method further comprises a polishing step of polishing the epitaxial substrate, and
in the polishing step, the epitaxial substrate is polished from a side of the third layer.
